(19) United States
(12) Patent Application Publication
(10) Pub. No.: US 2013/0104962 A1
(43) Pub. Date: May 2, 2013

(54) PHOTONIC ENERGY CONCENTRATORS WITH STRUCTURAL FOAM

(71) Applicant: Karl S. Weibezahn, Corvallis, OR (US)

(72) Inventor: Karl S. Weibezahn, Corvallis, OR (US)

(21) Appl. No.: 13/099,528

(22) Filed: May 3, 2011

(51) Int. Cl. H01L 31/052; H01L 31/0232; G02B 5/10

(52) U.S. Cl. CPC H01L 31/0525; G02B 5/10; H01L 31/02327
USPC 136/246; 359/853; 136/259; 29/428; 29/530

(57) ABSTRACT

Apparatus and methods related to photonic energy are provided. A device includes a reflector bearing a surface treatment and defining one or more photonic energy-concentrating areas. Target entities such as photovoltaic cells or thermal absorption conduits are disposed at the respective photonic energy-concentrating locations. A transparent cover can be used to protect the reflector. A foam material characterized by structural rigidity is disposed between and in contact with the backside of the reflector and a support housing. The assembled device resists bending, twisting or other deformation by virtue of the rigidity of the foam material.

### STATEMENT OF GOVERNMENT INTEREST

The invention that is the subject of this patent application was made with Government support under Subcontract No. CW135971, under Prime Contract No. HR0011-07-9-0005, through the Defense Advanced Research Projects Agency (DARPA). The Government has certain rights in this invention.

### BACKGROUND

Photovoltaic cells are solid-state devices that directly convert incident photonic energy, such as sunlight, into electrical energy. Other types of systems heat or boil water or other fluid media using solar radiation. Improvements to such devices and related systems are continuously sought after. The present teachings address the foregoing concerns.

### BRIEF DESCRIPTION OF THE DRAWINGS

The present embodiments will now be described, by way of example, with reference to the accompanying drawings, in which:

FIG. 1 depicts an end elevation section view of a device according to one example of the present teachings;

FIG. 2 depicts an isometric-like view of a device according to the present teachings;

FIG. 3 depicts an isometric-like view of a photonic energy concentrator according to the present teachings;

FIG. 4 depicts an end elevation section view of a device according to the present teachings;

FIG. 5 depicts a block diagram of a system according to the present teachings;

FIG. 6 depicts a flow diagram of a method according to the present teachings;

FIG. 7 depicts a flow diagram of another method according to the present teachings;

### DETAILED DESCRIPTION

### Introduction

Apparatus and methods related to photonic energy are provided. An illustrative device includes a reflector bearing a surface treatment and defining one or more photonic energy concentrating areas. Target entities such as photovoltaic cells or thermal absorption conduits are disposed at the respective photonic energy-concentrating locations or target regions. A transparent cover can be used to protect the reflector or the respective targets. Support housing is disposed about a backside aspect of the reflector.

A foam material, characterized by structural rigidity, is disposed between and in contact with the backside of the reflector and the support housing. The assembled device resists bending, twisting or other deformation by virtue of the rigidity of the foam material. Such devices can be used to derive electrical energy through direct conversion, heating or boiling of water or other heat transfer media, and so on.

In one example, a device includes a reflector to concentrate incident photonic energy onto a target location. The device also includes a housing disposed about a backside of the reflector such that an interstitial volume is defined. The device further includes a foam material disposed within the interstitial volume and in contact with the housing and the backside portion of the reflector. The device is characterized by a structural rigidity by virtue of the foam material.

In another example, a system includes a reflector array to concentrate incident photonic energy onto a plurality of respective target locations. The system also includes a plurality of photovoltaic cells to convert incident photonic energy into electrical energy. Each of the photovoltaic cells is disposed at a respective one of the target locations. The system also includes a housing disposed about a backside of the reflector array, such that an interstitial volume is defined between the housing and the reflector array. The system further includes a solid foam filling within the interstitial volume and in supportive contact with the housing and the backside of the reflector array. The system is characterized by rigidity in accordance with the solid foam.

In yet another example, a method includes joining a reflector array to a housing such that an interstitial volume is defined. The method also includes disposing a foam material within the interstitial volume. The foam material is characterized by structural rigidity when in a solid phase. The method also includes supporting at least one target entity at each of a plurality of target locations defined by the reflector array. The method further includes covering at least a portion of the reflector array with a transparent cover.

### First Illustrative Device

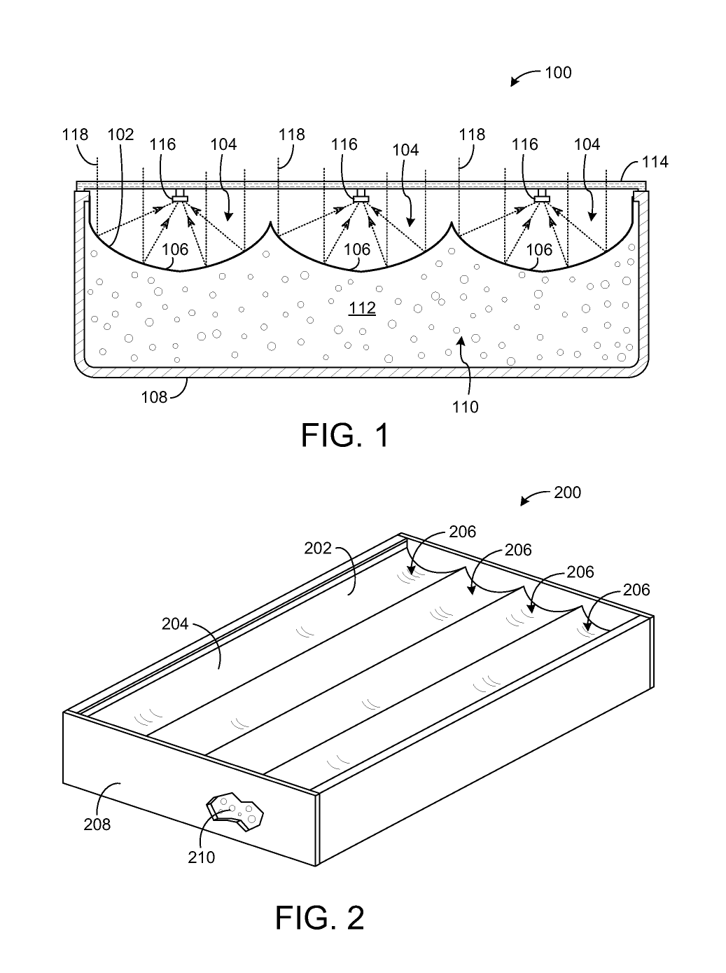

Reference is now directed to FIG. 1, which depicts an end elevation section view of a device 100. The device 100 is illustrative and non-limiting in nature. Thus, other devices, apparatus and systems are contemplated by the present teachings. The device 100 is also referred to as a photovoltaic device 100 for purposes herein.

The device 100 includes a reflector 102. The reflector 102 can be formed from material such as thermoplastic, plastic, metal, and so on. The reflector 102 is molded, folded, machined or formed in any suitable way to define a plurality of parallel troughs 104 defined by parabolic or semi-parabolic cross-sectional shapes. Thus, each trough 104 is also referred to as a parabolic trough 104. Other reflectors having other cross-sectional shapes can also be used. The reflector 102 is of relatively thin material and is generally lacking sufficient rigidity to be self-supporting under normal operating conditions.

The reflector 102 includes a reflective or dichroic surface treatment 106 such that each parabolic trough 104 is configured to concentrate incident photonic energy (e.g., sunlight) onto a respective target location. Such surface treatment 106 can be defined by or include one or more layers of aluminum, silver, silicon dioxide (SiO₂), titanium dioxide (TiO₂), niobium dioxide (NbO₂), or other suitable materials or compounds. In one example, the surface treatment 106 is defined by a thin layer of aluminum over-coated by a protective layer of silicon dioxide. Other surface treatments can also be used.

The device 100 also includes a support housing 108. The support housing 108 can be formed from thermoplastic, plastic, fiberglass, metal, and so on. Other suitable materials can also be used. The support housing 108 is generally box-like in shape and is disposed about a backside portion of the reflector 102. The reflector 102 is joined or bonded to the support housing 108 by way of adhesive, epoxy, laser or thermal welding, or in any other suitable way. An interstitial volume or space 110 is thus defined between the reflector 102 and the support housing 108.

The device 100 also includes a foam material 112 within the interstitial volume 110. The foam material 112 can be any suitable foam material that cures to a solid phase and is characterized by a suitable structural rigidity. In one embodiment, the foam material 112 is defined by a closed-cell polyurethane foam characterized by a weight density in the range of about one-point-five to about forty pounds per cubic foot (i.e., about 1.5 Lb/Ft³ to about 40 Lb/Ft³). Other suitable foam materials 112 can also be used.

In one example, the foam material 112 is introduced into the interstitial volume 110 as an expanding, fluid-flow which then conforms to the shape of the reflector 102 and the support housing 108 and cures to a solid state in situ. In another example, the foam material 112 is formed as a discrete entity and then placed within the interstitial volume 110 during the assembly of the device 100. Other suitable constructions or procedures can also be used.

The device 100 also includes a transparent cover 114. The transparent cover 114 can be formed from glass, acrylic, plastic, or another suitable material. The transparent cover 114 overlies and functions to protect the reflector 102 against weather and other ambient conditions. The transparent cover 114 is bonded or suitably joined to the support housing 108 about a periphery thereof.

The device 100 further includes a plurality of photovoltaic (PV) cells 116. Each of the PV cells 116 is supported on an underside of the transparent cover 114 and is disposed to receive concentrated photonic energy (i.e., sunlight) from a corresponding one of the parabolic troughs 104. That is, each of the PV cells 116 is disposed at or along a target location defined by a respective one of the parabolic troughs 104. The PV cells 116 are configured to generate electrical energy in response to concentrated photonic energy incident thereon. The PV cells 116 are understood to be electrically coupled to an external load which consumes the generated electrical energy during normal operations of the device 100.

The device 100 is characterized by a structural rigidity by virtue of the foam material 112 within the interstitial volume 110. This structural rigidity is substantially greater than would otherwise be achieved by the reflector 102 and the support housing 108 operating without the foam material 112. The foam material 112 therefore acts to prevent or resist folding, bending, torsional twisting or other deformation of the device 100 under wind load, snow load or other environmental forces that can occur during normal use.

Additionally, the foam material 112 is in contact with most or all (at least a majority portion) of the backside surface area of the reflector 102 and the interior wall area of the support housing 108. This characteristic functions to maintain the desired cross-sectional shape of the respective parabolic troughs 104 of the reflector 102.

Normal, illustrative operations involving the device 100 are as follows: several PV cells 116 are disposed in supported contact with the transparent cover 114. Photonic energy, depicted by illustrative light rays 118, passes through the transparent cover 114 and is incident upon the reflector 102. The photonic energy or a spectral portion thereof is concentrated onto the respective PV cells 116 by way of the parabolic troughs 104 having the surface treatment 106.

The PV cells 116 generate or derive electrical energy from the photonic energy by direct conversion. The electrical energy is then electrically coupled to an external entity or load (e.g., load 516). The foam material 112 operates to maintain structural rigidity and geometric form of the device 100 during such illustrative operations despite potentially adverse ambient conditions such as wind, rain, and so on.

### Second Illustrative Device

Attention is now turned to FIG. 2, which depicts an isometric-like view of a device 200. The device 200 is illustrative and non-limiting in nature. Thus, other devices, apparatus and systems are contemplated by the present teachings. The device 200 is also referred to as a solar energy device 200 for purposes herein. In one example, structural aspects of the device 200 are analogous to those of the device 100.

The device 200 includes a reflector 202. The reflector 202 can be formed from thermoplastic, plastic, fiberglass, metal or another suitable material. The reflector 202 includes a reflective surface treatment 204. In one example, the reflective surface treatment 204 is defined by a layer of aluminum metal overlaid with a protective layer of silicon dioxide. Other surface treatments 204 can also be used.

The reflector 202 is formed to include a total of four parallel troughs 206 each defined by a parabolic cross-sectional shape. Each of the troughs 206 is also referred to as a parabolic trough 206 for purposes herein. Each of the troughs 206 is configured to concentrate photonic energy (e.g., sunlight) along a strip-like target location or region by virtue of the reflective surface treatment 204. Such target location is not depicted in the interest of clarity.

The device 200 also includes a housing or support housing 208. The housing 208 is disposed about a backside portion of the reflector 202 and can be formed of the same or a compatible material such as thermoplastic, metal, and so on. An interstitial volume is defined between the reflector 202 and the housing 208 and is filled with a solidified foam material 210. In one example, the foam material 210 is defined by closed-cell polyurethane foam having a cured density of about two pounds per cubic foot (i.e., 2.0 Lb/Ft³). Other foam materials 210 can also be used.

The device 200 is illustrative of a photonic energy concentrator that can be used with photovoltaic cells, thermal-absorption piping, or other loads. An illustrative reflective surface treatment 204 is described above. In another example, the surface treatment 204 is defined by one or more layers of dichroic material(s) such that a selected spectral portion of incident light energy is concentrated onto the respective target locations. Operating characteristics of the target entities (e.g., PV cells) can be selected in accordance with the concentrated spectral content in such an embodiment.

### Illustrative Double-Curved Concentrator

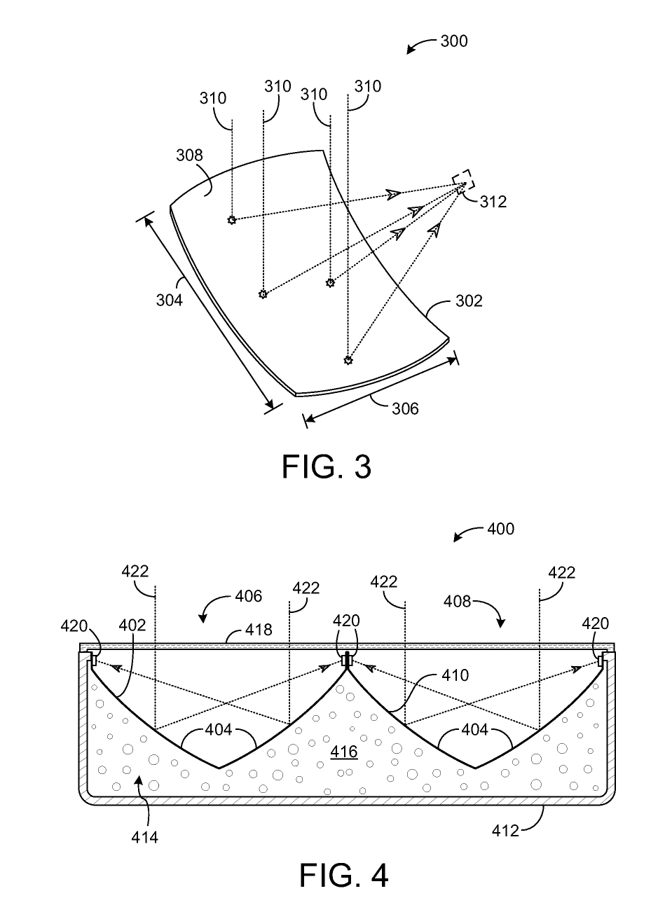

Reference is now made to FIG. 3, which depicts an isometric-like view of a photonic energy concentrator (concentrator) 300. The concentrator 300 is illustrative and non-limiting with respect to the present teachings. Other concentrators, devices and systems are also contemplated and can be used.

The concentrator 300 is formed from a sheet material 302. The sheet material 302 can be defined by or include thermoplastic, metal, or another suitable material. The sheet material 302 is characterized by a first parabolic curvature along a lengthwise aspect 304. The sheet material 302 is also characterized by a second parabolic curvature along a widthwise aspect 306. The concentrator 300 is therefore characterized by a dual parabolic curvature. The concentrator 300 is therefore referred to as a double-curvature concentrator 300 for purposes of the present teachings.

The concentrator 300 also includes a surface treatment 308 on the concave side or “face” of the sheet material 302. In one example, the surface treatment 308 is reflective in nature. In another example, the surface treatment 308 is made up of one or more dichroic materials. The concentrator 300 is configured to concentrate incident photonic energy—illustrated by four respective light rays 310—onto a spot-like target location 312. Thus, the double-curvature concentrator 300 functions to concentrate light onto a relatively small region.

### Third Illustrative Device

Reference is now directed to FIG. 4, which depicts an end elevation section view of a device 400. The device 400 is illustrative and non-limiting in nature. Thus, other devices, apparatus and systems are contemplated by the present teachings. The device 400 is also referred to as a photovoltaic device 400 for purposes herein.

The device 400 includes a reflector 402. The reflector 402 can be formed from material such as thermoplastic, plastic, metal, and so on. The reflector 402 is molded, folded, machined or formed in any suitable way to define a plurality of double-curvature concentrators 404.

The reflector 402 includes a reflective or dichroic surface treatment 410 such that each concentrator 404 is configured to concentrate incident photonic energy (e.g., sunlight) onto a respective target location. Thus, each of the concentrators 404 is analogous to the concentrator 300 described above. Such surface treatment 410 can be defined by or include one or more layers of aluminum, silver, silicon dioxide (SiO₂), titanium dioxide (TiO₂), niobium dioxide (NbO₂), or other suitable materials or compounds. In one example, the surface treatment 410 is defined by a thin layer of aluminum over-coated by a protective layer of silicon dioxide. Other surface treatments can also be used.

The reflector 402 is defined by two respective rows 406 and 408, each having a plurality of concentrators 404 arranged as respective, inward-facing pairs. Each row 406 and 408 can include any suitable number of pairs of concentrators 404 such that the reflector 402 defines an array of concentrators 404. In one example, the reflector 402 includes twelve pairs of concentrators 404, arranged as two rows 406 and 408 of six pairs each, for a total of twenty-four concentrators 404. Other configurations can also be used.

The device 400 also includes a support housing 412. The support housing 412 can be formed from thermoplastic, plastic, fiberglass, metal, and so on. Other suitable materials can also be used. The support housing 412 is generally box-like in shape and is disposed about a backside portion of the reflector 402. The reflector 402 is joined or bonded to the support housing 412 by way of adhesive, epoxy, laser or other thermal welding, or any other suitable way. An interstitial volume or space 414 is thus defined between the reflector 402 and the support housing 412.

The device 400 also includes a foam material 416 within the interstitial volume 414. The foam material 416 can be any suitable foam material that cures to a solid phase and is characterized by a suitable structural rigidity. In one embodiment, the foam material 416 is closed-cell polyurethane foam as described above. Other suitable foam materials 416 can also be used.

In one example, the foam material 416 is introduced as an expanding, fluid-flow into the interstitial volume 414 which then conforms to the shape of the reflector 402 and the support housing 412 and cures to a solid state in situ. In another example, the foam material 416 is formed as a discrete entity and then placed within the interstitial volume 414 during assembly. Other suitable constructions or procedures can also be used.

The device 400 also includes a transparent cover 418. The transparent cover 418 can be formed from glass, acrylic, plastic, or another suitable material. The transparent cover 418 overlies and functions to protect the reflector 402 against weather or other ambient conditions. The transparent cover 418 is bonded or suitably joined to the support housing 412.

The device 400 further includes a plurality of photovoltaic (PV) cells 420. Each of the PV cells 420 is supported on a respective vertical wall portion of the reflector 402 and is disposed to receive concentrated photonic energy from a corresponding one of the photonic energy concentrators 404. Thus, each of the PV cells 420 is disposed at a target location defined by a respective one of the concentrators 404. The PV cells 420 are configured to generate electrical energy in response to concentrated photonic energy incident thereon. The PV cells 420 are understood to be electrically coupled to an external load (e.g., load 516) which consumes the generated electrical energy during normal operations of the device 400.

The device 400 is characterized by a structural rigidity by virtue of the foam material 416 with in the interstitial volume 414. The structural rigidity is substantially greater than would otherwise be achieved by the reflector 402 and the support housing 412 in the absence of the foam material 416. The foam material 416 therefore acts to prevent or resist folding, bending, twisting or other deformation of the device 400 under wind load, snow load or other environmental forces that can occur during normal use.

Additionally, the foam material 416 is in contact with at least a majority portion of the backside surface area of the reflector 402 and the interior wall area of the support housing 412. In this way, the desired shapes of the respective concentrators 404 of the reflector 402 are maintained during normal use.

Normal, illustrative operations involving the device 400 are as follows: PV cells 420 are supported beneath the transparent cover 418 and at respective target locations defined by the concentrators 404. Photonic energy, depicted by illustrative light rays 422, passes through the transparent cover 418 and is incident upon the reflector 402. The photonic energy or a spectral portion thereof is concentrated onto the respective PV cells 420 by way of the photonic energy concentrators 404.

The PV cells 420 derive electrical energy from the photonic energy by direct conversion. The electrical energy is then electrically coupled to an external entity or load. The foam material 416 operates to maintain structural rigidity and geometric form of the device 400 during such normal operations despite potentially adverse ambient conditions such as wind, rain, and so on.

### Illustrative System Block Diagram

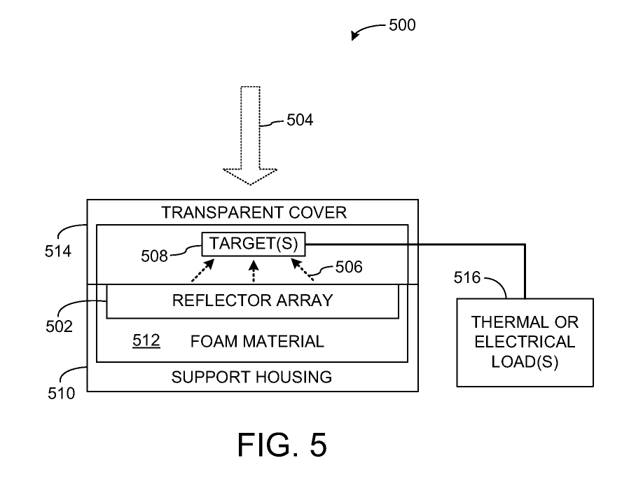

Attention is now directed to FIG. 5, which depicts a block diagram of a system 500 according to the present teachings. The system 500 is illustrative and non-limiting in nature, and other systems, devices and apparatus can be defined and used according to the present teachings. The system 500 is intended to illustrate the present teachings in a generalized format, and is neither exhaustive nor limiting in that respect.

The system 500 includes a reflector array 502. The reflector array 502 is formed from thermoplastic, plastic, fiberglass, metal or another relatively thin, sheet-like material. The reflector array 502 is bears a reflective or dichroic surface treatment (e.g., 106) and includes respective formed surface areas such that incident photonic energy 504 becomes concentrated photonic energy 506 onto one or more targets 508.

The system 500 further includes a support housing 510. The support housing 510 can be formed from thermoplastic, fiberglass, metal, and so on. The support housing 510 is disposed generally beneath and about a backside aspect of the reflector array 502. The system 500 also includes a foam material 512 disposed between and in contact with the reflector array 502 and the support housing 510. In one example, the foam material 512 is formed independently and is disposed in place during assembly of the system 500. In another example, the foam material 512 is injected between the reflector array 502 and the support housing 510 and expands into contact therewith, curing to a solidified state in place. The foam material 512 is characterized by a structural rigidity when solid that serves to maintain the desired geometric shape of the reflector array 502 during mechanical loading incident to normal operation.

The system 500 also includes a transparent cover 514. The transparent cover 514 can be formed from glass, plastic, acrylic, or another suitable material. The transparent cover 514 protects the reflector array 502 against potentially damaging factors such as snow, rain, wind blown dust and so on during normal use.

The system 500 also includes one or more targets 508 as introduced above. Each of the targets 508 can be respectively defined by a photovoltaic cell, a fluid-filled heat-transfer conduit, and so on. Other suitable targets 508 can also be used. Each of the targets 508 is disposed to receive concentrated photonic energy 506 from a respective portion or concentrator of the reflector array 502. As such, each of the targets 508 is configured to operate in accordance with its own specific characteristics.

The system 500 further includes one or more thermal or electrical loads 516 coupled to receive a corresponding form of energy from the one or more targets 508. In one example, the load 516 is defined by an electronic apparatus such as a radio transceiver that is electrically coupled to a plurality of photovoltaic cells (targets) 508. In another example, the load 516 is defined by a liquid vessel that receives or stores a flow of heated water by way of a heat transfer conduit (target) 508. Other configurations can also be used.

The system 500 depicts the target(s) 508 as being disposed within the protective scope of the transparent cover 514. However, it is to be understood that other suitable configurations can be used respectively including one or more targets 508 disposed outside of (i.e., remote from) the transparent cover 514.

### First Illustrative Method

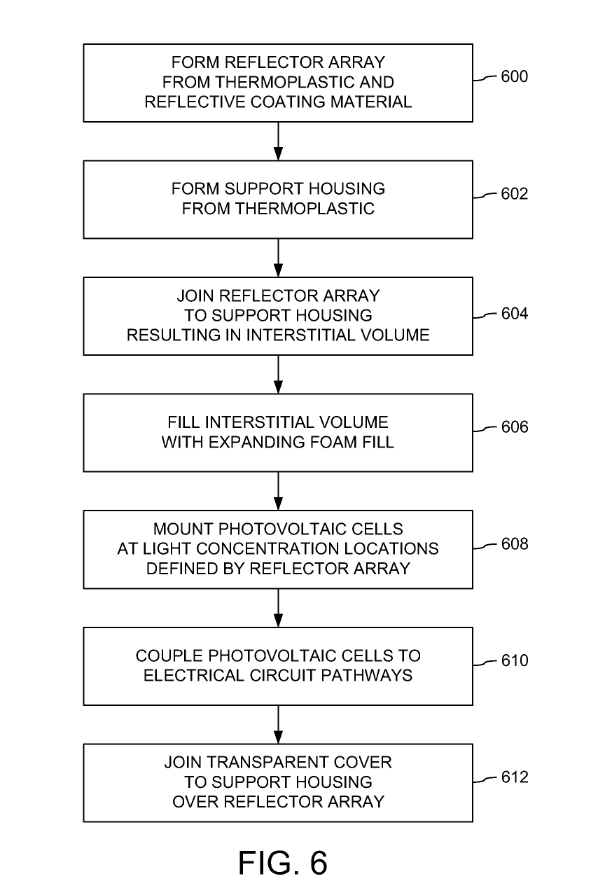

Reference is now made to FIG. 6, which depicts a flow diagram of a method according to another example of the present teachings. The method of FIG. 6 includes particular steps and proceeds in a particular order of execution. However, it is to be understood that other respective methods including other steps, omitting one or more of the depicted steps, or proceeding in other orders of execution can also be used. Thus, the method of FIG. 6 is illustrative and non-limiting with respect to the present teachings. Reference is also made to FIG. 1 in the interest of understanding the method of FIG. 6.

At 600, a reflector array is formed from thermoplastic and a reflective coating. For purposes of a present illustration, thermoplastic is used to form a reflector 102 defining a trio of parabolic troughs 104. The thermoplastic is coated with a light-reflecting layer of aluminum and is over-coated with silicon dioxide to collectively define a surface treatment 106. The

At 602, a support housing is formed from thermoplastic. For purposes of the present example, a support housing 108 is formed from the same type of thermoplastic as the reflector 102. The support housing 108 is generally box-like in shape and is configured to be disposed about a backside portion of the reflector 102.

At 604, the reflector array is joined to the support housing resulting in an interstitial volume. For purposes of the present example, the reflector 102 is joined to the support housing 108 by way of laser welding, thus defining an interstitial volume 110.

At 606, the interstitial volume is filled with an expanding foam fill material. For purposes of the present example, a foam material 112 is introduced or injected into the interstitial volume 110. The foam material 112 expands into supportive contact with the backside of the reflector 102 and the interior walls of the support housing 108. The foam material 112 then solidifies or cures in place to a solid state.

At 608, photovoltaic cells are mounted at light concentration locations defined by the reflector array. For purposes of the present example, respective PV cells 116 are mounted along support rails of a transparent cover 114. This places the PV cells 116 at light concentration or target locations defined by of the respective parabolic troughs 104, once the transparent cover is disposed in place over the reflector 102 (i.e., step 612 below). Thus, three respective rows of PV cells 116, being arranged end-to-end within each row, are supported by the transparent cover 114.

At 610, the photovoltaic cells are electrically coupled to electrical circuit pathways. For purposes of the present example, the PV cells 116 are electrically coupled to respective circuit pathways or conductors such that an electrical array is defined. The circuit pathways are configured to be coupled to an external or remote electrical load.

At 612, the transparent cover is joined to the support housing thus covering the reflector array. For purposes of the present example, the transparent cover 114 is disposed over the reflector 102 and is bonded to the support housing by way of laser welding, adhesive, or in another suitable way. The PV cells 116 are thus disposed and supported at the respective strip-like target locations defined by the parabolic troughs 104 of the reflector 102. A finished and assembled photovoltaic device 100 is thus defined.

### Second Illustrative Method

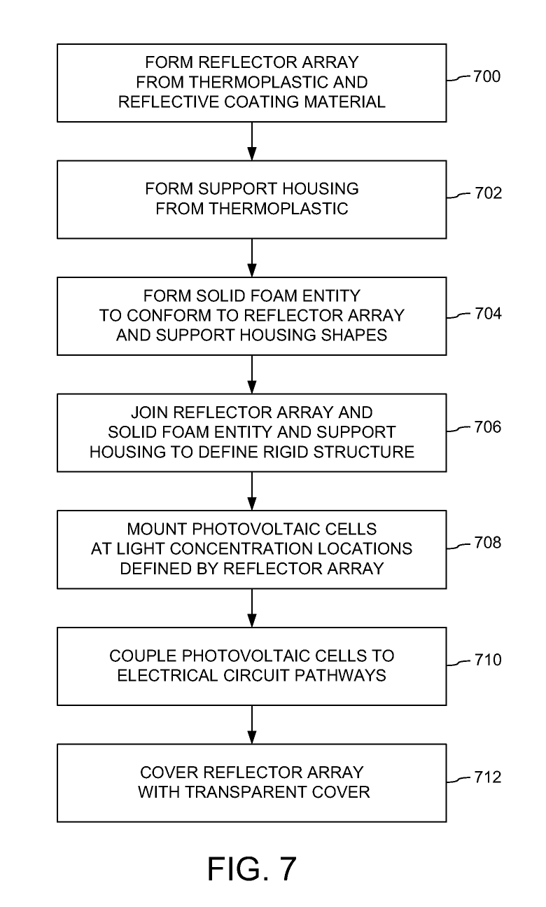

Attention is now directed to FIG. 7, which depicts a flow diagram of a method according to another example of the present teachings. The method of FIG. 7 includes particular steps and proceeds in a particular order of execution. However, it is to be understood that other respective methods including other steps, omitting one or more of the depicted steps, or proceeding in other orders of execution can also be used. Thus, the method of FIG. 7 is illustrative and non-limiting with respect to the present teachings. Reference is also made to FIG. 1 in the interest of understanding the method of FIG. 7.

At 700, a reflector array is formed from thermoplastic and a reflective coating. For purposes of a present illustration, a reflector array 102 is formed from thermoplastic such that a trio of parabolic troughs 104 is defined. The thermoplastic is coated with a light-reflecting layer of aluminum and is over-coated with silicon dioxide to collectively define a surface treatment 106.

At 702, a support housing is formed from thermoplastic. For purposes of the present example, a support housing 108 is formed from the same thermoplastic as that of the reflector 102. The support housing 108 is generally box-like in shape and is configured to be disposed about a backside portion of the reflector 102.

At 704, a solid foam entity is formed to conform to the shapes of the reflector array and the support housing. For purposes of the present example, a foam material 112 is formed by molding, machining or other suitable method so as to conform to the backside shape of the reflector 102 and the interior of the support housing 108. The foam material 112 is therefore is a solid, discrete entity prior to proceeding to the next method step.

At 706, the reflector array and the solid foam entity and the support housing are joined to define a rigid structure. For purposes of the present example, the foam material 112 is brought into supportive contact with the backside of the reflector 102, and is in turn received within the support housing 108. The reflector 102 is then joined or bonded to the support housing about the periphery be laser welding, an adhesive, or another suitable way.

At 708, photovoltaic cells are mounted at light concentration locations defined by the reflector array. For purposes of the present example, respective PV cells 116 are mounted along support rails of a transparent cover 114. The PV cells 116 are therefore placed at light concentration or target locations defined by of the respective parabolic troughs 104, once the transparent cover is disposed in place over the reflector 102 (i.e., step 712 below). In this example, three respective rows of PV cells 116 arranged as end-to-end elements within each row are supported by the transparent cover 114.

At 710, the photovoltaic cells are electrically coupled to electrical circuit pathways. For purposes of the present example, the PV cells 116 are electrically coupled to respective circuit pathways or conductors such that an electrical array is defined. The circuit pathways are configured to be coupled to an external or remote electrical load.

At 712, the transparent cover is joined to the support housing thus covering the reflector array. For purposes of the present example, the transparent cover 114 is disposed over the reflector 102 and is bonded to the support housing by way of laser welding, adhesive, or in another suitable way. The PV cells 116 are thus disposed and supported at the respective strip-like target locations defined by the parabolic troughs 104 of the reflector 102. A finished and assembled photovoltaic device 100 is thus defined.

In general and without limitation, the present teachings contemplate solar energy devices and systems and methods of their use. A device includes a relatively thin reflector formed from thermoplastic or another suitable material. The reflector is shaped, molded or machined as needed such that one or more light concentrating geometries are defined. Non-limiting examples of such geometries include parabolic troughs, segmented parabolic concentrators, double-curvature concentrator or “dish-like” shapes, and so on. Other suitable surface shapes can also be used. A single reflector can include any suitable number of distinct light concentrators or surface areas such that a reflector array is defined.

A surface treatment is applied, deposited, formed or bonded to the reflector. This surface treatment can be defined by a reflective material, one or more layers of dichroic material(s), an over-coating of protective material such as silicon dioxide, and so on. The surface treatment is such that at least a spectral portion of photonic energy incident to the reflector is concentrated onto target locations defined by the respective light concentrating surface geometries. For example, a parabolic trough would concentrate photonic energy onto an elongated strip-like target location or region. In another example, a double-curvature concentrator would concentrate photonic energy onto a spot-like target location or region.

A support housing is formed from a material such as thermoplastic, fiberglass, or another suitable material. The support housing is shaped to be disposed about a backside portion of the reflector. Joining the support housing to the reflector defines an interstitial volume there between that is filled or nearly so with a foam material. The foam material can be introduced into the interstitial volume as expanding foam that cure or hardens in place. Alternatively, the foam material can be pre-formed as a separate and distinct entity that is placed into the interstitial volume during assembly.

The foam material is in supportive contact with at least a majority portion of the backside of the reflector, as well as the inside wall surfaces of the support housing. The foam material is characterized by a structural rigidity when solidified. The structural rigidity of the foam material functions to resist bending, folding, twisting or other deformation of the reflector or support housing when the finished assemblage is subject to environment forces such as wind, snow, rain, and so on.

Energy absorbing or energy conversion targets are secured in place at the respective light concentrating target locations defined by the geometries and surface treatment of the reflector. Such targets can include photovoltaic cells, thermal energy absorbing fluid conduits, and so on. The targets can be defined by respective operating characteristics consistent with the spectral content to which each target is exposed.

For example, a fluid-filled conduit can receive concentrated thermal energy from a parabolic trough bearing a dichroic surface treatment that reflects photonic energy within an infrared spectral band. In another example, a mid-energy photovoltaic cell can be disposed to receive a matching spectral band of photonic energy from a double-curvature concentrator. Other configurations and target/concentrator combinations can also be used.

A transparent cover can be formed from any suitable material and joined to the support housing so as to protect the reflector array. The transparent cover can, in some examples, function to support the one or more target entities at the respective target locations. The transparent cover can also be bonded to the support housing about a periphery thereof. Such bonding or joining can be permanent or the transparent cover can be removably joined by way of mechanical fasteners, and so on.

In general, the foregoing description is intended to be illustrative and not restrictive. Many embodiments and applications other than the examples provided would be apparent to those of skill in the art upon reading the above description. The scope of the invention should be determined, not with reference to the above description, but should instead be determined with reference to the appended claims, along with the full scope of equivalents to which such claims are entitled. It is anticipated and intended that future developments will occur in the arts discussed herein, and that the disclosed systems and methods will be incorporated into such future embodiments. In sum, it should be understood that the invention is capable of modification and variation and is limited only by the following claims.

What is claimed is:

1. A device, comprising:
a reflector to concentrate incident photonic energy onto a target location;
a housing disposed about a backside of the reflector such that an interstitial volume is defined; and
a foam material within the interstitial volume and in contact with the housing and the backside portion of the reflector, the device characterized by a structural rigidity by virtue of the foam material.

2. The device according to claim 1 further comprising a photovoltaic cell disposed at the target location.

3. The device according to claim 1, the reflector formed from a thermoplastic, the reflector including a front side having a reflective or dichroic surface treatment thereon.

4. The device according to claim 1, the housing formed from a thermoplastic.

5. The device according to claim 1 further comprising a transparent cover disposed over the reflector and in contact with the housing.

6. The device according to claim 1, the reflector formed to define a parabolic trough so as to concentrate incident photonic energy onto a strip-like target location.

7. The device according to claim 1, the reflector defined by a first parabolic curvature and a second parabolic curvature orthogonal to the first parabolic curvature so as to concentrate incident photonic energy onto a spot-like target location.

8. The device according to claim 1 further comprising a thermal absorption conduit disposed at the target location.

9. A system, comprising:
a reflector array to concentrate incident photonic energy onto a plurality of respective target locations;
a plurality of photovoltaic cells to convert incident photonic energy into electrical energy, each of the photovoltaic cells disposed at a respective one of the target locations;
a housing disposed about a backside of the reflector array such that an interstitial volume is defined between the housing and the reflector array; and
a solid foam within the interstitial volume and in supportive contact with the housing and the backside of the reflector array, the system characterized by a rigidity in accordance with the solid foam.

10. The system according to claim 9, the reflector array formed from a material characterized by flexibility, the reflector array being rigidly supported by way of the solid foam.

11. The system according to claim 9, at least the reflector array or the housing formed from a plastic, a thermoplastic, a carbon fiber, or a fiberglass material.

12. The system according to claim 9, the reflector array having a front side with at least one surface area bearing a reflective or a dichroic material.

13. The system according to claim 9, the reflector array defining respective pairs of double-curved reflectors, each double-curved reflector within a pair configured to concentrate incident photonic energy onto a spot-like target location proximate to an upper edge of the other double-curved reflector of that pair.

14. The system according to claim 9, the reflector array defining a plurality of parallel parabolic troughs, each parabolic trough configured to concentrate incident photonic energy onto a strip-like target location.

15. A method, comprising:
joining a reflector array to a housing such that an interstitial volume is defined;
disposing a foam material within the interstitial volume, the foam material characterized by structural rigidity when in a solid phase;
supporting at least one target entity at each of a plurality of target locations defined by the reflector array; and
covering at least a portion of the reflector array with a transparent cover.

16. The method according to claim 16, the foam material disposed within the interstitial volume by either:
flowing an expanding foam material into the interstitial volume, the expanding foam material allowed to cure to a solid phase in situ; or
disposing a preformed solid foam entity within the interstitial volume.
